(19) United States
(12) Patent Application Publication
(10) Pub. No.: US 2026/0197002 A1
(43) Pub. Date: Jul. 9, 2026

(54) BIDIRECTIONAL LEVEL CONVERSION CIRCUIT

(71) Applicant: uPI semiconductor corp., Zhubei City (TW)

(72) Inventor: Shao-Lin FENG, Zhubei City (TW)

(21) Appl. No.: 19/401,511

(22) Filed: Nov. 26, 2025

(30) Foreign Application Priority Data
Jan. 8, 2025 (TW) 114100717

(51) Int. Cl. H03K 19/0185

(52) U.S. Cl. CPC H03K 19/018507

(57) ABSTRACT

A bidirectional level conversion circuit is disclosed. The bidirectional level conversion circuit includes a first shifting circuit, a second shifting circuit and an OR gate. The first shifting circuit generates a first shifting signal according to the input signal. The second shifting circuit and the first shifting circuit operate on mutually exclusive voltage domains and connected in parallel to generate a second shifting signal according to the input signal. Two input terminals of the OR gate are coupled to output terminals of the first shifting circuit and the second shifting circuit, and generate output signals according to the first shifting signal and the second shifting signal. The first shifting circuit includes a resistor, a MOS and a current source connected in series. The second shifting circuit includes a first voltage domain circuit, a first MOS, a second MOS and a second voltage domain circuit connected in series.

### BACKGROUND OF THE INVENTION

### 1. Field of the invention

The invention relates to a level conversion circuit; in particular, to a bidirectional level conversion circuit.

### 2. Description of the prior art

Please refer to FIG. 1. FIG. 1 is a schematic diagram of a conventional driver output structure. As shown in FIG. 1, HV_VCC and HV_GND are an operating voltage and a ground voltage of a high-voltage domain circuit respectively. During system operation, the ground voltage HV_GND of the high-voltage domain circuit may have three voltage levels: (1) when a switch signal UG is at high-level H and a switch signal LG is at low-level L, a transistor N2 is turned on and a transistor N1 is turned off. The voltage level of the ground voltage HV_GND of the high-voltage domain circuit is the input voltage VIN; (2) when the switch signal UG is at low-level L and the switch signal LG is at high-level H, the transistor N2 is turned off and the transistor N1 is turned on. The voltage level of the ground voltage HV_GND of the high-voltage domain circuit is the ground voltage GND; (3) when the switch signals UG and LG are both at low-level L, both the transistors N1 and N2 are turned off. The ground voltage HV_GND of the high-voltage domain circuit will drop to a negative voltage NV due to the output current IOUT being drawn through the diode D1, as shown in FIG. 2. This abnormal negative voltage NV will affect the circuit module connected to the HV_GND pin of the driver, especially causing the level shifter not to work properly.

### SUMMARY OF THE INVENTION

Therefore, the invention provides a bidirectional level conversion circuit to solve the above-mentioned problems of the prior arts.

A preferred embodiment of the invention is a bidirectional level conversion circuit. In this embodiment, the bidirectional level conversion circuit converts an input signal in a first voltage domain into an output signal in a second voltage domain. The bidirectional level conversion circuit includes a first shifting circuit, a second shifting circuit and an OR gate. The first shifting circuit is configured to generate a first shifting signal according to the input signal. The second shifting circuit and the first shifting circuit operate on mutually exclusive voltage domains and are connected in parallel to generate a second shifting signal according to the input signal. Two input terminals of the OR gate are respectively coupled to the output terminals of the first shifting circuit and the second shifting circuit, and are configured to generate output signals according to the first shifting signal and the second shifting signal. The first shifting circuit includes a resistor, a MOS and a current source connected in series with each other. The second shifting circuit includes a first voltage domain circuit, a first MOS, a second MOS and a second voltage domain circuit connected in series with each other.

Compared to the prior art, the bidirectional level conversion circuit proposed in this invention utilizes a conventional first shifting circuit in parallel with a second shifting circuit for negative voltage application, so that it can avoid the voltage dropout region and convert the low-voltage input signal into the high-voltage output signal, or vice versa, to achieve signal transmission. Therefore, the bidirectional level conversion circuit of this invention not only operates normally at negative voltage, but also has no operating current at high-voltage, so the system power consumption can be reduced effectively.

The advantage and spirit of the invention may be understood by the following detailed descriptions together with the appended drawings.

### BRIEF DESCRIPTION OF THE APPENDED DRAWINGS

The accompanying drawings of the invention are described as follows:

FIG. 1 is a schematic diagram of a conventional driver output structure.

FIG. 2 is a waveform diagram showing that a ground voltage of a high-voltage domain circuit may have three voltage levels.

FIG. 3 is a schematic diagram showing that a bidirectional level conversion circuit converts a high-voltage domain input signal into a low-voltage domain output signal in a specific embodiment of the invention.

FIG. 4 is a schematic diagram of a level conversion circuit having a conventional high-voltage domain circuit operating voltage to ground voltage structure.

FIG. 5A is a waveform diagram showing a ground voltage of a high-voltage domain circuit, an input signal of a high-voltage domain, an output signal of a low-voltage domain, a second shifting signal and a first shifting signal.

FIG. 5B is a waveform diagram showing that an output signal of a low-voltage domain transits smoothly when a ground voltage of a high-voltage domain circuit is a positive voltage.

FIG. 5C is a waveform diagram showing that an output signal of a low-voltage domain cannot transit when a ground voltage of a high-voltage domain circuit is a negative voltage.

FIG. 6 is a schematic diagram showing that a bidirectional level conversion circuit converts a low-voltage domain input signal into a high-voltage domain output signal in a specific embodiment of the invention.

FIG. 7 is a schematic diagram of a level conversion circuit having a conventional high-voltage domain circuit operating voltage to ground voltage structure.

FIG. 8A is a waveform diagram of a ground voltage of a high-voltage domain circuit, an input signal of a low-voltage domain, an output signal of a high-voltage domain, a third shifting signal and a fourth shifting signal.

FIG. 8B is a waveform diagram showing that an output signal of a high-voltage domain transits smoothly when a ground voltage of a high-voltage domain circuit is a positive voltage.

FIG. 8C is a waveform diagram showing that an output signal of a high-voltage domain cannot transit when a ground voltage of a high-voltage domain circuit is a negative voltage.

FIG. 9 is a schematic diagram showing that a second shifting circuit converts a high-voltage domain input signal into a low-voltage domain second shifting signal.

FIG. 10 is a schematic diagram showing that a second shifting circuit converts a low-voltage domain input signal into a high-voltage domain second shifting signal.

FIG. 11 is a schematic diagram showing that a second shifting circuit converts a high-voltage input signal into a low-voltage second shifting signal.

FIG. 12 is a schematic diagram showing that a second shifting circuit converts a low-voltage input signal into a high-voltage second shifting signal.

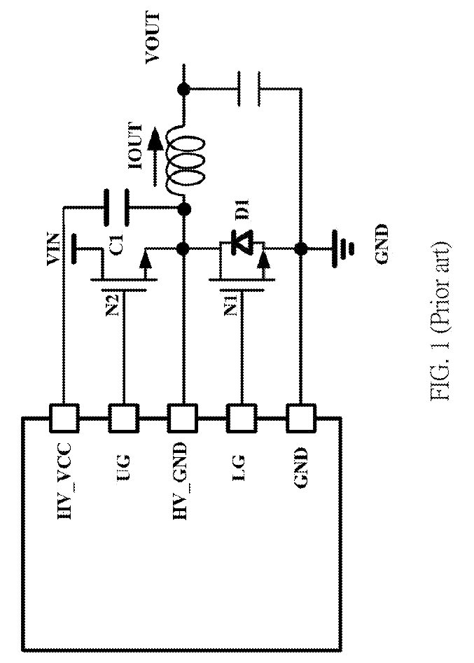

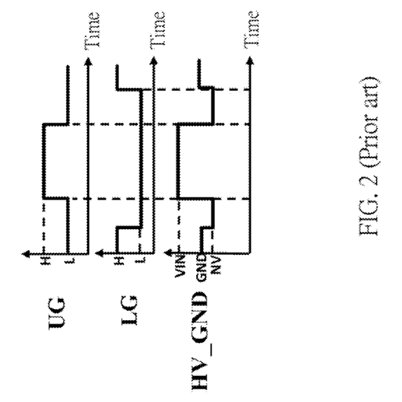

### DETAILED DESCRIPTION OF THE INVENTION

Exemplary embodiments of the invention are referenced in detail now, and examples of the exemplary embodiments are illustrated in the drawings. Further, the same or similar reference numerals of the components/components in the drawings and the detailed description of the invention used on behalf of the same or similar parts.

A specific embodiment of the invention is a bidirectional level conversion circuit. The term “bidirectional” means that both high-voltage domain and low-voltage domain is converted to each other, for example, from a 3.3V voltage domain to a 12V voltage domain, or from a 5.5V voltage domain to a 3.3V voltage domain, depending on the actual needs of the user.

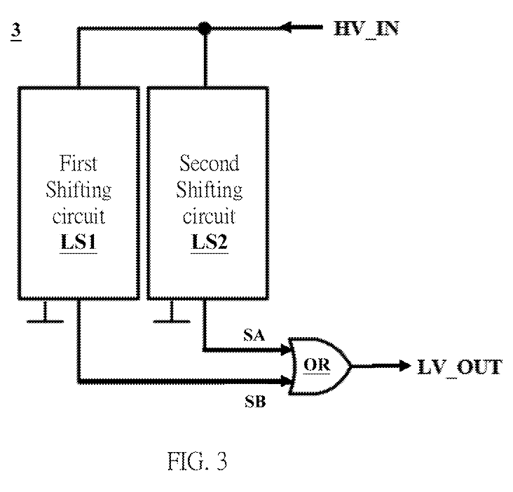

Please refer to FIG. 3. FIG. 3 is a schematic diagram of a bidirectional level conversion circuit 3 converting a high-voltage domain input signal HV_IN to a low-voltage domain output signal LV_OUT in this embodiment. As shown in FIG. 3, the bidirectional level conversion circuit 3 includes a first shifting circuit LS1, a second shifting circuit LS2 and an OR gate OR. The first shifting circuit LS1 and the second shifting circuit LS2 are connected in parallel and operate in mutually exclusive voltage domains. The first shifting circuit LS1 is configured to generate a first shifting signal SB according to the high-voltage domain input signal HV_IN. The second shifting circuit LS2 is configured to generate a second shifting signal SA according to the high-voltage domain input signal HV_IN. Two input terminals of the OR gate OR are respectively coupled to the output terminals of the first shifting circuit LS1 and the second shifting circuit LS2 for generating a low-voltage domain output signal LV_OUT according to the first shifting signal SB and the second shifting signal SA.

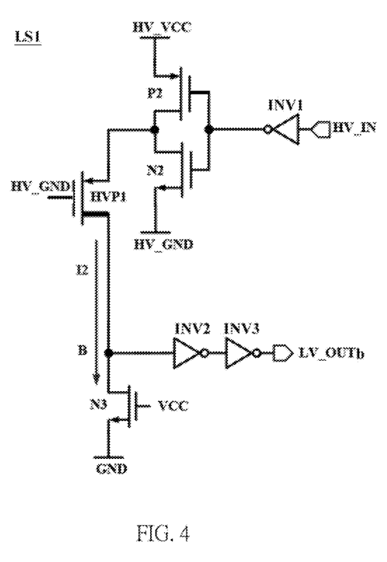

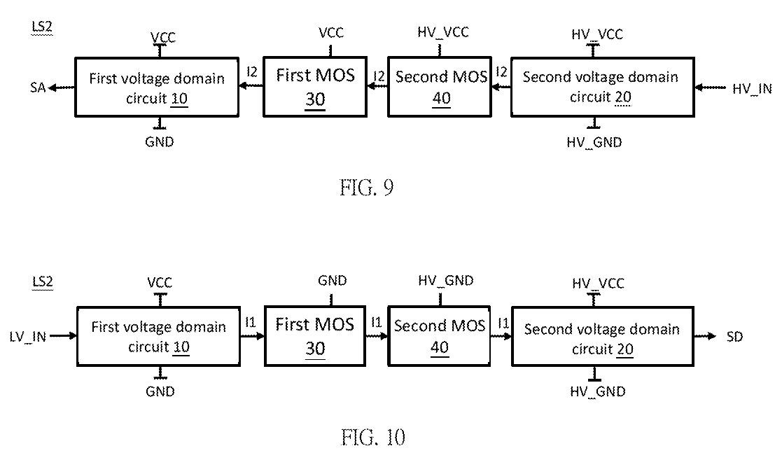

It notes that the first shifting circuit LS1 could be, for example, a level conversion circuit having a conventional high-voltage domain circuit operating voltage HV_VCC to ground voltage GND structure as shown in FIG. 4. In the first shifting circuit LS1, the transistor P2 and the transistor N2 are connected in series between the high-voltage domain circuit operating voltage HV_VCC and the high-voltage domain circuit ground voltage HV_GND. The gates of the transistors P2 and N2 receive the high-voltage domain input signal HV_IN and operate in the high-voltage domain. The transistor N3 is coupled between the high-voltage transistor HVP1 and the low-voltage domain circuit ground voltage GND. The gate of the transistor N3 receives the low-voltage domain circuit operating voltage VCC and operates in the low-voltage domain. The high-voltage transistor HVP1 is coupled to the transistor P2, the transistor N2 and the transistor N3 respectively. The gate of the high-voltage transistor HVP1 receives the high-voltage domain circuit ground voltage HV_GND and operates in the high-voltage domain, but not limited to this. A node B is located between the high-voltage transistor HVP1 and the transistor N3. The high-voltage transistor HVP1 and the transistor P2 are P-type transistors, and the transistor N2 and the transistor N3 are N-type transistors, but not limited to this. The second shifting circuit LS2 can be, for example, a negative voltage level conversion circuit having a structure in which the operating voltage VCC of the low-voltage domain circuit applies to the ground voltage HV_GND of the high-voltage domain circuit, as shown in FIG. 9, but not limited to this.

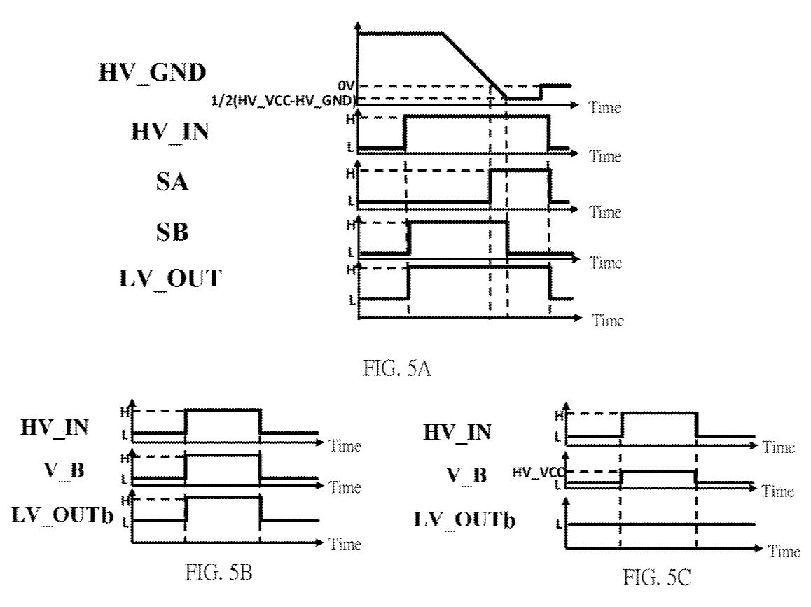

FIG. 5A is a waveform diagram of the ground voltage HV_GND of the high-voltage domain circuit, the input signal HV_IN of the high-voltage domain, the output signal LV_OUT of the low-voltage domain, the second shifting signal SA, and the first shifting signal SB. When the ground voltage HV_GND of the high-voltage domain circuit is at a negative voltage (less than 0V), the input signal HV_IN of the high-voltage domain maintains at high-level. However, because a voltage difference between the operating voltage HV_VCC and the ground voltage GND of the high-voltage domain circuit is less than 1/2 (HV_VCC-HV_GND), the first shifting signal SB transits from high-level to low-level. The second shifting circuit LS2, which operates for negative voltages, transits to normal operation after the ground voltage HV_GND of the high-voltage-domain circuit falls within its operating range, causing the second shifting signal SA to transit from low-level to high-level. The first shifting signal SB and the second shifting signal SA are combined through an OR gate OR to generate the low-voltage-domain output signal LV_OUT, which fully reflects the high-voltage-domain input signal HV_IN, and completes signal transmission.

The first scenario relating the ground voltage HV_GND of the high-voltage domain circuit is a positive voltage, as shown in FIG. 5B. When the input signal HV_IN of the high-voltage domain circuit transits, a node voltage V_B of the node B in the first shifting circuit LS1 of FIG. 4 can rise to a sufficiently large voltage difference to cause the output signal LV_OUTb of the low-voltage domain to transit. The second scenario relating ground voltage HV_GND of the high-voltage domain circuit is a negative voltage, also as shown in FIG. 5C. During the input signal HV_IN of the high-voltage domain circuit transits, the voltage drop between the operating voltage HV_VCC and the ground voltage GND of the high-voltage domain circuit is less than 1/2 (HV_VCC-HV_GND). Hence, the node voltage V_B of the node B in the first shifting circuit LS1 of FIG. 4 can only rise to the operating voltage HV_VCC of the high-voltage domain circuit, causing the output signal LV_OUT of the low-voltage domain to be unable to transit.

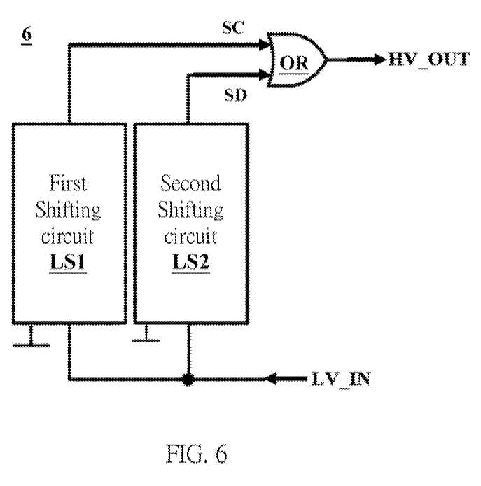

Please refer to FIG. 6. FIG. 6 is a schematic diagram of a bidirectional level conversion circuit 6 converting a low-voltage domain input signal LV_IN into a high-voltage domain output signal HV_OUT in this embodiment. As shown in FIG. 6, the bidirectional level conversion circuit 6 includes a first shifting circuit LS1, a second shifting circuit LS2 and an OR gate OR. The first shifting circuit LS1 and the second shifting circuit LS2 are connected in parallel and operate in mutually exclusive voltage domains. As shown in FIG. 6, the first shifting circuit LS1 is configured to generate a third shifting signal SC according to the low-voltage domain input signal LV_IN. The second shifting circuit LS2 is configured to generate a fourth shifting signal SD according to the low-voltage domain input signal LV_IN. The two input terminals of the OR gate OR are respectively coupled to the output terminals of the first shifting circuit LS1 and the second shifting circuit LS2, and configured to generate a high-voltage domain output signal HV_OUT according to the third shifting signal SC and the fourth shifting signal SD.

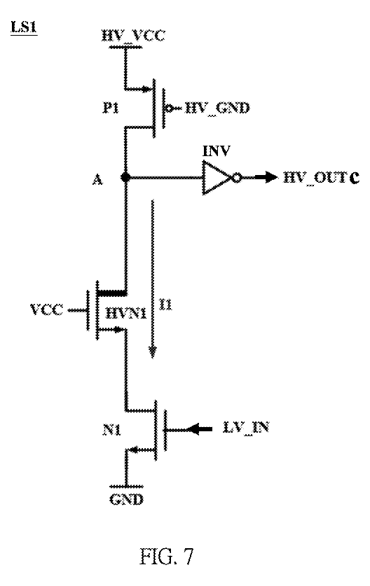

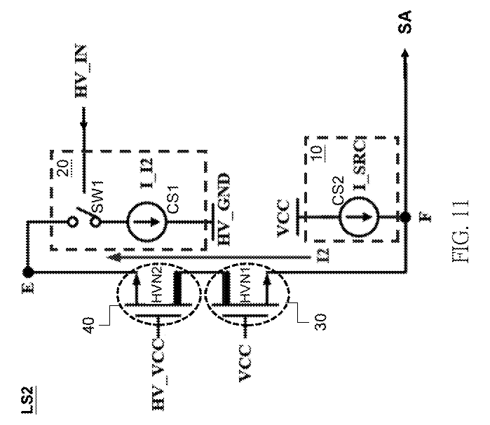

It noted that the first shifting circuit LS1 could be, for example, a level conversion circuit having a conventional high-voltage domain circuit operating voltage HV_VCC to ground voltage GND structure as shown in FIG. 7. In the first shifting circuit LS1, the transistor P1, the high-voltage transistor HVN1 and the transistor N1 are connected in series between the high-voltage domain circuit operating voltage HV_VCC and the low-voltage domain circuit ground voltage GND. A gate of the transistor P1 receives the high-voltage domain circuit ground voltage HV_GND and operates in the high-voltage domain. A gate of the transistor N1 receives the low-voltage domain input signal LV_IN and operates in the low-voltage domain. A gate of the high-voltage transistor HVN1 receives the low-voltage domain circuit operating voltage VCC and operates in the low-voltage domain, but not limited to this. A node A is located between the transistor P1 and the high-voltage transistor HVN1. The high-voltage transistor HVN1 and the transistor N1 are N-type transistors, and the transistor P1 is a P-type transistor, but not limited to this. The second shifting circuit LS2 can be, for example, a level shifting circuit for negative voltage application has a structure in which the operating voltage VCC applies to the ground voltage HV_GND of the high-voltage domain circuit, as shown in FIG. 10, but not limited to this.

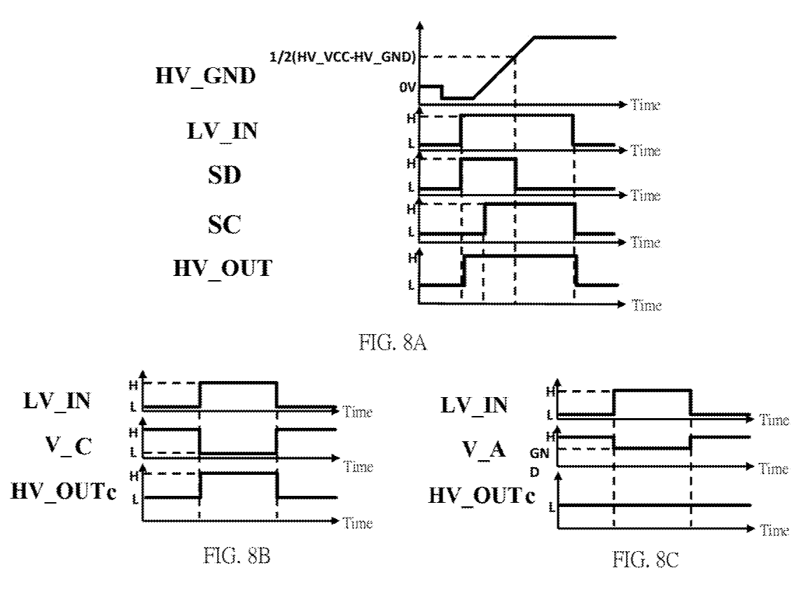

FIG. 8A is a waveform diagram of the ground voltage HV_GND of the high-voltage domain circuit, the input signal LV_IN of the low-voltage domain, the output signal HV_OUT of the high-voltage domain, the third shifting signal SC and the fourth shifting signal SD. The figure shows one scenario relating the ground voltage HV_GND of the high-voltage domain circuit is at a negative voltage (less than 0V). In this time, the input signal LV_IN of the low-voltage domain transits, a voltage difference between the operating voltage HV_VCC and the ground voltage GND of the high-voltage domain circuit is less than 1/2 (HV_VCC-HV_GND), causing the third shifting signal SC to fail to transit. However, at this time, the second shifting circuit LS2 for negative voltage application operates normally, so that the fourth shifting signal SD normally reflects the input signal LV_IN of the low-voltage domain. After the high-voltage domain output signal HV_OUT transits, the ground voltage HV_GND of the high-voltage domain circuit rises, resuming operation of the conventional first shifting circuit LS1 and completing the transition of the third shifting signal SC. As the ground voltage HV_GND of the high-voltage domain circuit rising, disabling the negative-voltage second shifting circuit LS2, the third shifting signal SC and the fourth shifting signal SD are combined through the OR gate OR to generate the high-voltage domain output signal HV_OUT, which fully reflects the low-voltage domain input signal LV_IN and completes signal transmission.

The first scenario relating the ground voltage HV_GND of the high-voltage domain circuit is a positive voltage, as shown in FIG. 8B. During the input signal LV_IN of the low-voltage domain transits, a node voltage V_C at the node C in the first shifting circuit LS1 of FIG. 7 drop sufficiently large voltage to cause the output signal HV_OUTc of the high-voltage domain to transit. The second scenario relating the ground voltage HV_GND of the high-voltage domain circuit is a negative voltage, as shown in FIG. 8C. During the input signal LV_IN of the low-voltage domain transits, the voltage across the operating voltage HV_VCC and the ground voltage GND of the high-voltage domain circuit is less than 1/2 (HV_VCC - HV_GND). Therefore, the node voltage V_C at the node C in the first shifting circuit LS1 of FIG. 7 drop to the ground voltage GND limit, preventing the output signal HV_OUTc of the high-voltage domain from transiting.

FIG. 9 is a circuit block diagram of the second shifting circuit LS2 that converts the input signal HV_IN of the high-voltage domain into the second shifting signal SA of the low-voltage domain. The second shifting circuit LS2 includes a first voltage domain circuit 10, a first MOS 30, a second MOS 40 and a second voltage domain circuit 20 connected in series with each other. The first voltage domain circuit 10 is coupled between the operating voltage VCC and the ground voltage GND of the low-voltage domain circuit and operates in the low-voltage domain. The second voltage domain circuit 20 is coupled between the operating voltage HV_VCC and the ground voltage HV_GND of the high-voltage domain circuit, and operates in the high-voltage domain. A gate of the first MOS 30 receives the operating voltage VCC of the low-voltage domain circuit so operates in the low-voltage domain. A gate of the second MOS 40 receives the operating voltage HV_VCC of the high-voltage domain circuit so operates in the high-voltage domain. The second voltage domain circuit 20 operating in the high-voltage domain receives the input signal HV_IN of the high-voltage domain and generates a second current I2. The second current I2 is sequentially transmitted to the first voltage domain circuit 10 operating in the low-voltage domain via the second MOS 40 operating in the high-voltage domain and the first MOS 30 operating in the low-voltage domain. The first voltage domain circuit 10 operating in the low-voltage domain then outputs a second shifting signal SA to the OR gate OR.

When the high-voltage domain input signal HV_IN transits from low-level L to high-level H, the first MOS 30 and the second MOS 40 are turned off. A voltage across the second voltage domain circuit 20 is less than half a voltage difference between the operating voltage VCC of the low-voltage domain circuit and the ground voltage GND of the low-voltage domain circuit. The second shifting signal SA outputted by the first voltage domain circuit 10 transit from low-level L to high-level H, and the low-voltage domain output signal LV_OUT outputted by the OR gate OR also transits from low-level L to high-level H, thereby completing signal transmission.

During the high-voltage domain input signal HV_IN transiting from high-level H to low-level L, the first MOS 30 and the second MOS 40 are turned on. Afterwards, the second current I2 generated by the second voltage domain circuit 20 flows sequentially through the second MOS 40 and the first MOS 30 to the first voltage domain circuit 10. It causes a voltage across the second voltage domain circuit 20 to be greater than or equal to half a voltage difference between the operating voltage VCC of the low-voltage domain circuit and the ground voltage GND of the low-voltage domain circuit. This causes the second shifting signal SA outputted by the first voltage domain circuit 10 to transit from high-level H to low-level L, and the low-voltage domain output signal LV_OUT outputted by the OR gate OR also transits from high-level H to low-level L, thereby completing signal transmission.

FIG. 10 is a schematic diagram showing that the second shifting circuit LS2 converts the input signal LV_IN in the low-voltage domain into a fourth shifting signal SD in the high-voltage domain. The second shifting circuit LS2 includes a first voltage domain circuit 10, a first MOS 30, a second MOS 40 and a second voltage domain circuit 20 connected in series with each other. The first voltage domain circuit 10 is coupled between the operating voltage VCC of the low-voltage domain circuit and the ground voltage GND of the low-voltage domain circuit, and operates in the low-voltage domain. The second voltage domain circuit 20 is coupled between the operating voltage HV_VCC of the high-voltage domain circuit and the ground voltage HV_GND of the high-voltage domain circuit, and operates in the high-voltage domain. A gate of the first MOS transistor 30 receives the ground voltage GND of the low-voltage domain circuit and operates in the low-voltage domain. A gate of the second MOS transistor 40 receives the ground voltage HV_GND of the high-voltage domain circuit and operates in the high-voltage domain. The first voltage domain circuit 10 operating in the low-voltage domain receives the low-voltage domain input signal LV_IN and then generates a first current I1. Then, the first current I1 flows sequentially through the first MOS transistor 30 operating in the low-voltage domain and the second MOS transistor 40 operating in the high-voltage domain to the second voltage domain circuit 20 operating in the high-voltage domain. The second voltage domain circuit 20 operating in the high-voltage domain then outputs a fourth shifting signal SD to the OR gate OR.

During the input signal LV_IN of the low-voltage domain transits from low-level L to high-level H, the first MOS 30 and the second MOS 40 are turned on. It makes the first current I1 generated by the first voltage domain circuit 10 flow sequentially through the first MOS 30 and the second MOS 40 to the second voltage domain circuit 20. Hence, it brings about the voltage across the second voltage domain circuit 20 to be greater than or equal to half a voltage difference between the operating voltage HV_VCC of the high-voltage domain circuit and the ground voltage HV_GND of the high-voltage domain circuit. This also causes the fourth shifting signal SD outputted by the second voltage domain circuit 20 to transit from low-level L to high-level H, and the high-voltage domain output signal HV_OUT outputted by the OR gate OR also transits from low-level L to high-level H, thereby completing signal transmission.

In other case, when the low-voltage domain input signal LV_IN transiting from high-level H to low-level L, the first MOS transistor 30 and the second MOS transistor 40 are turned off. It makes a voltage across the second voltage domain circuit 20 be less than half a voltage difference between the operating voltage HV_VCC of the high-voltage domain circuit and the ground voltage HV_GND of the high-voltage domain circuit. This causes the fourth shifting signal SD outputted by the first voltage domain circuit 10 to transit from high-level H to low-level L, and the high-voltage domain output signal HV_OUT outputted by the OR gate OR also transits from high-level H to low-level L, thereby completing signal transmission.

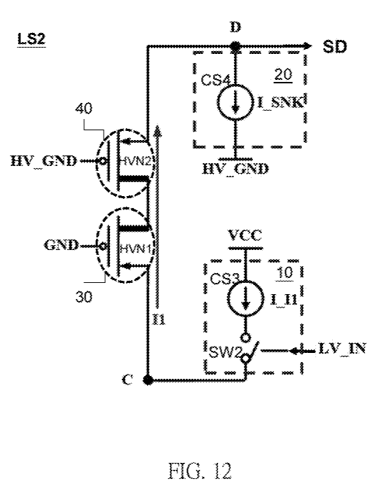

FIG. 11 is a schematic diagram of an embodiment of a second shifting circuit LS2 that converts the high-voltage domain input signal HV_IN into a low-voltage domain second shifting signal A. As shown in FIG. 11, the second shifting circuit LS2 includes a first voltage domain circuit 10, a first MOS 30, a second MOS 40 and a second voltage domain circuit 20 connected in series with each other. The first voltage domain circuit 10 includes a current source CS2 coupled between the operating voltage VCC of the low-voltage domain circuit and a node F. The second voltage domain circuit 20 includes a switch SW1 and a current source CS1, connected in series between a node E and the ground voltage HV_GND of the high-voltage domain circuit. The switch SW1 is controlled by the high-voltage domain input signal HV_IN. The second MOS 40 and the first MOS 30 are connected in series between the nodes E and F, with the drain terminals of the second MOS 40 and the first MOS 30 connected to each other to provide voltage protection. The node F outputs a second shifting signal A of the low-voltage domain. Both the second MOS 40 and the first MOS 30 are high-voltage N-type metal oxide semiconductor field-effect transistors. A gate of the second MOS 40 is coupled to the operating voltage HV_VCC of the high-voltage domain circuit, and operates in the high-voltage domain. A gate of the first MOS 30 is coupled to the operating voltage VCC of the low-voltage domain circuit, and operates in the low-voltage domain. A current I_I2 generated by the current source CS1, the second MOS 40, and the first MOS 30 generate a signal transmission current I2 from the operating voltage VCC of the low-voltage domain circuit to the ground voltage HV_GND of the high-voltage domain circuit. When the signal transmission current I2 is greater than a preset current I_SRC generated by the current source CS2, a node voltage V_F at the node F transits, completing signal transmission from the high-voltage domain to the low-voltage domain.

We noted the scenario relating the second shifting circuit LS2 for negative voltage application primarily transmitting signals through the operating voltage VCC of the low-voltage domain circuit to the ground voltage HV_GND of the high-voltage domain circuit. In the case, the conventional first shifting circuit LS1, which transmits signals from the operating voltage HV_VCC of the high-voltage domain circuit to the ground voltage GND of the low-voltage domain circuit, is subject to a cross-voltage limit of the operating voltage HV_VCC of the high-voltage domain circuit to the ground voltage GND of the low-voltage domain circuit. Hence, the second shifting circuit LS2 for negative voltage applications also has a failure problem. Therefore, the bidirectional level conversion circuit of the invention uses the first shifting circuit LS1 and the second shifting circuit LS2 connected in parallel to avoid the failure voltage region and successfully complete signal transmission.

FIG. 12 is a schematic diagram of an embodiment of the second shifting circuit LS2 for converting the low-voltage domain input signal LV_IN into the fourth shifting signal SD of the high-voltage domain. As shown in FIG. 12, the second shifting circuit LS2 includes a first voltage domain circuit 10, a first MOS 30, a second MOS 40 and a second voltage domain circuit 20 connected in series with each other. The first voltage domain circuit 10 includes a current source CS3 and a switch SW2, coupled between the operating voltage VCC of the low-voltage domain circuit and the node C. The second voltage domain circuit 20 includes a current source CS4, connected in series between the node D and the ground voltage HV_GND of the high-voltage domain circuit. The switch SW2 is controlled by the low-voltage domain input signal LV_IN. The second MOS 40 and the first MOS 30 are connected in series between the nodes D and C, with the drain terminals of the second MOS 40 and the first MOS 30 connected to each other to provide voltage protection. The node D outputs the fourth shifting signal SD of the high-voltage domain. Both the second MOS 40 and the first MOS 30 are high-voltage P-type metal oxide semiconductor field-effect transistors. A gate of the second MOS 40 is coupled to the ground voltage HV_GND of the high-voltage domain circuit, and operates in the high-voltage domain. A gate of the first MOS transistor 30 is coupled to the ground voltage GND of the low-voltage domain circuit, and operates in the low-voltage domain. The current I_I1 generated by the current source CS3, the second MOS 40, and the first MOS 30 generate a signal transmission current I1 from the operating voltage VCC of the low-voltage domain circuit to the ground voltage HV_GND of the high-voltage domain circuit. When the signal transmission current I1 is greater than a preset current I_SNK generated by the current source CS4, the node voltage V_D at the node D transits, completing signal transmission from the low-voltage domain to the high-voltage domain.

Compared to the prior art, the bidirectional level conversion circuit proposed in this invention utilizes a conventional first shifting circuit in parallel with a second shifting circuit for negative voltage application, so that it can avoid the voltage dropout region and convert the low-voltage input signal into the high-voltage output signal, or vice versa, to achieve signal transmission. Therefore, the bidirectional level conversion circuit of this invention not only operates normally at negative voltage, but also has no operating current at high-voltage, so the system power can effectively reduce power consumption.

With the example and explanations above, the characteristics and spirits of the invention well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A bidirectional level conversion circuit for converting an input signal in a first voltage domain into an output signal in a second voltage domain, comprising:
a first shifting circuit, configured to generate a first shifting signal according to the input signal;
a second shifting circuit, configured to operate on mutually exclusive voltage domains with the first shifting circuit and connected in parallel with the first shifting circuit to generate a second shifting signal according to the input signal; and
an OR gate having two input terminals being respectively coupled to output terminals of the first shifting circuit and the second shifting circuit, and being configured to generate output signals according to the first shifting signal and the second shifting signal;
wherein the first shifting circuit comprises a resistor, a MOS and a current source connected in series with each other; the second shifting circuit comprises a first voltage domain circuit, a first MOS, a second MOS and a second voltage domain circuit connected in series with each other.

2. The bidirectional level conversion circuit of claim 1, wherein the first voltage domain circuit is coupled between an operating voltage and a ground voltage of a low-voltage domain circuit and operates in a low-voltage domain; the second voltage domain circuit is coupled between an operating voltage and a ground voltage of a high-voltage domain circuit and operates in a high-voltage domain.

3. The bidirectional level conversion circuit of claim 2, wherein when the input signal is a low-voltage domain input signal and the output signal is a high-voltage domain output signal, a gate of the first MOS receives the ground voltage of the low-voltage domain circuit and operates in the low-voltage domain; a gate of the second MOS receives the ground voltage of the high-voltage domain circuit and operates in the high-voltage domain.

4. The bidirectional level conversion circuit of claim 3, wherein when the low-voltage domain input signal transits from low-level to high-level, the first MOS and the second MOS are turned on, and the first voltage domain circuit generates a first current that flows sequentially through the first MOS and the second MOS to the second voltage domain circuit, so that a voltage across the second voltage domain circuit is greater than or equal to half a difference between the operating voltage of the high-voltage domain circuit and the ground voltage of the high-voltage domain circuit, causing the second shifting signal outputted by the second voltage domain circuit to transit from low-level to high-level, and the high-voltage domain output signal also transits from low-level to high-level.

5. The bidirectional level conversion circuit of claim 3, wherein when the low-voltage domain input signal transits from high-level to low-level, the first MOS and the second MOS are turned off, and a voltage across the second voltage domain circuit is less than half a difference between the operating voltage of the high-voltage domain circuit and the ground voltage of the high-voltage domain circuit, causing the first shifting signal outputted by the first voltage domain circuit to transit from high-level to low-level, and the high-voltage domain output signal also transits from high-level to low-level.

6. The bidirectional level conversion circuit of claim 2, wherein when the input signal is a high-voltage domain input signal and the output signal is a low-voltage domain output signal, a gate of the first MOS receives the operating voltage of the low-voltage domain circuit and becomes a low-voltage domain MOS; a gate of the second MOS receives the operating voltage of the high-voltage domain circuit and becomes a high-voltage domain MOS.

7. The bidirectional level conversion circuit of claim 6, wherein when the high-voltage domain input signal transits from low-level to high-level, the first MOS and the second MOS are turned off, a voltage across the second voltage domain circuit is less than half a difference between the operating voltage of the low-voltage domain circuit and the ground voltage of the low-voltage domain circuit, causing the first shifting signal outputted by the first voltage domain circuit to transit from low-level to high-level, and the low-voltage domain output signal also transits from low-level to high-level.

8. The bidirectional level conversion circuit of claim 6, wherein when the high-voltage domain input signal transits from high-level to low-level, the first MOS and the second MOS are turned on, and the second voltage domain circuit generates a second current that flows sequentially through the second MOS and the first MOS to the first voltage domain circuit, so that a voltage across the second voltage domain circuit is greater than or equal to half a difference between the operating voltage of the low-voltage domain circuit and the ground voltage of the low-voltage domain circuit, causing the first shifting signal outputted by the first voltage domain circuit to transit from high-level to low-level, and the low-voltage domain output signal also transits from high-level to low-level.

9. The bidirectional level conversion circuit of claim 3, wherein in the first shifting circuit, the resistor is coupled between the operating voltage of the high-voltage domain circuit and the MOS, the current source is coupled between the MOS and the ground voltage of the low-voltage domain circuit, and a gate of the MOS receives the operating voltage of the low-voltage domain circuit and operates in the low-voltage domain.

10. The bidirectional level conversion circuit of claim 6, wherein in the first shifting circuit, the current source is coupled between the operating voltage of the high-voltage domain circuit and the MOS, the resistor is coupled between the MOS and the ground voltage of the low-voltage domain circuit, and a gate of the MOS receives the ground voltage of the high-voltage domain circuit and operates in the high-voltage domain.
